(19) United States
(12) Patent Application Publication
(10) Pub. No.: US 2024/0215417 A1
(43) Pub. Date: Jun. 27, 2024

(54) LIGHT-EMITTING ELEMENT

(71) Applicant: CANON KABUSHIKI KAISHA, Tokyo (JP)

(72) Inventor: TOSHIYUKI OGAWA, Chiba (JP)

(21) Appl. No.: 18/538,340

(22) Filed: Dec. 13, 2023

(30) Foreign Application Priority Data
Dec. 23, 2022 (JP) 2022-206722

(51) Int. Cl. H10K 59/80; H10K 59/122

(52) U.S. Cl. CPC H10K 59/8792; H10K 59/122; H10K 59/879

(57) ABSTRACT

A light-emitting element includes a pixel, an emitter disposed in the pixel, and a light-shielding layer configured to shield light emitted by the emitter. The emitter includes a first light-emitting portion and a second light-emitting portion which emits light of an emission color of the first light-emitting portion, the light-shielding layer includes a first opening portion where light emitted by the first light-emitting portion transmits through, and a second opening portion where light emitted by the second light-emitting portion transmits through, and an opening area of the second opening portion is smaller than an opening area of the first opening portion.

### BACKGROUND OF THE INVENTION

### Field of the Invention

The technique of the present disclosure relates to a self-emitting type light-emitting element.

### Description of the Related Art

In the recent development of organic electroluminescence (EL) light-emitting elements, a multi-gradation technique for each pixel is being developed as a way of improving image quality.

Japanese Patent Application Publication No. 2015-102723 discloses a display device integrating large light-emitting elements, small light-emitting elements of which light-emitting region is narrower than the large light-emitting elements, and a current control circuit.

In the case of Japanese Patent Application Publication No. 2015-102723, however, the large light-emitting elements and the small light-emitting elements need to be formed separately, and a driving circuit and a driving method, optimized for each type of light-emitting element, must be used, hence the structure and driving method of the display device tend to become complicated.

### SUMMARY OF THE INVENTION

With the foregoing in view, it is an object of the present disclosure to provide a technique to implement multi-gradation of each pixel without complicating the configuration of the circuit to drive the light-emitting element.

According to some embodiments, a light-emitting element includes a pixel, an emitter disposed in the pixel, and a light-shielding layer configured to shield light emitted by the emitter, wherein the emitter includes a first light-emitting portion and a second light-emitting portion which emits light of an emission color of the first light-emitting portion, he light-shielding layer includes a first opening portion where light emitted by the first light-emitting portion transmits through, and a second opening portion where light emitted by the second light-emitting portion transmits through, and an opening area of the second opening portion is smaller than an opening area of the first opening portion.

Further features of the present invention will become apparent from the following description of exemplary embodiments with reference to the attached drawings.

### BRIEF DESCRIPTION OF THE DRAWINGS

FIGS. 1A and 1B are schematic diagrams depicting a structure of a light-emitting element according to First Embodiment;

FIG. 2 is a graph depicting driving of a light-emitting element according to an embodiment;

FIG. 3 is a graph depicting a light-emitting characteristic of the light-emitting element according to an embodiment;

FIGS. 4A and 4B are schematic diagrams depicting a structure of a light-emitting element according to Second Embodiment;

FIG. 5 is a schematic diagram depicting a structure of a light-emitting element according to Thid Embodiment;

FIG. 6 is a schematic diagram depicting a structure of the light-emitting element according to Third Embodiment;

FIGS. 7A and 7B are schematic diagrams depicting a structure of another light-emitting element according to Third Embodiment;

FIG. 8 is a schematic diagram depicting a structure of still another light-emitting element according to Third Embodiment;

FIG. 9 is a diagram depicting an example of a display device according to an embodiment;

FIGS. 10A and 10B are diagrams depicting an example of an imaging device and an electronic apparatus according to an embodiment;

FIGS. 11A and 11B are diagrams depicting an example of a display device according to an embodiment;

FIGS. 12A and 12B are diagrams depicting an example of an illumination device and a car having a lighting unit according to an embodiment; and

FIGS. 13A and 13B are diagrams depicting an example of a wearable device according to an embodiment.

### DESCRIPTION OF THE EMBODIMENTS

Embodiments of the present disclosure will now be described with reference to the drawings. The present disclosure is not limited to the following embodiments, but may be changed appropriately within a scope not departing from the spirit thereof. In the following drawings to be described, composing elements having a same function are denoted with a same reference sign, and the description thereof may be omitted or simplified.

### First Embodiment

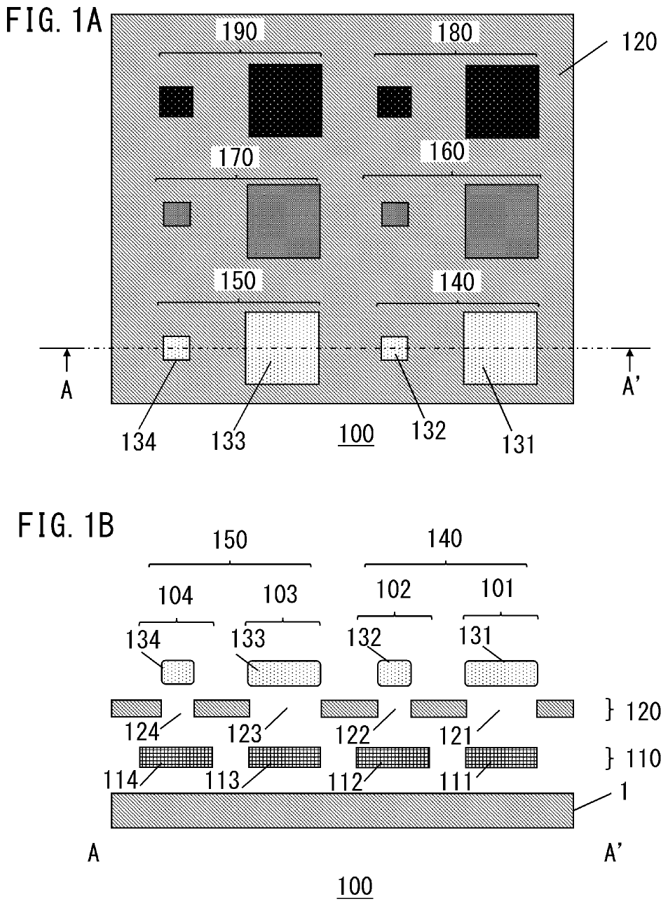

A light-emitting element according to First Embodiment will be described with reference to FIGS. 1A and 1B. FIG. 1A is a schematic top view of the light-emitting element 100 according to First Embodiment, and FIG. 1B is a schematic cross-sectional view of the light-emitting element 100, and indicates a cross-section of the light-emitting element 100 sectioned at the A-A′ line in FIG. 1A.

In the light-emitting element 100, a plurality of pixels 140, 150, 160, 170, 180 and 190 are disposed on a substrate 1, and as illustrated in FIG. 1B, a first light-emitting portion 101 and a second light-emitting portion 102 are disposed in one pixel 140. In the same manner, a first light-emitting portion 103 and a second light-emitting portion 104 are disposed in the pixel 150. Further, in the light-emitting element 100, an emitter corresponding to each light-emitting portion is disposed on the substrate 1. The emitter is an organic electroluminescence (EL) element here, but may be a different element. The first light-emitting portions 101 and 103 correspond to the first light-emitting portion, and the second light-emitting portions 102 and 104 correspond to the second light-emitting portion that emits light of the emission color of the first light-emitting portion.

As illustrated in FIG. 1B, an emitter 111 corresponding to the first light-emitting portion 101 of the pixel 140 and an emitter 112 corresponding to the second light-emitting portion 102 of the pixel 140 are disposed. In the same manner, an emitter 113 corresponding to the first light-emitting portion 103 of the pixel 150 and an emitter 114 corresponding to the second light-emitting portion 104 of the pixel 150 are disposed. In the following description, the emitters 111 to 114 are referred to as an emitter 110.

A light-shielding layer 120 is disposed on the upper part of the emitter 110, and in the light-shielding layer 120, opening portions 121 to 124 are formed at positions corresponding to the light-emitting portions 101 to 104 respectively. In the following description, an opening portion corresponding to the first light-emitting portion 101 of the pixel 140 is called a first opening portion 121, and an opening portion corresponding to the second light-emitting portion 102 of the pixel 140 is called a second opening portion 122. In the same manner, a first opening portion 123 and a second opening portion 124, which are similar to the first opening portion 121 and the second opening portion 122, are also formed in the pixel 150. The first opening portions 121 and 123 correspond to the first opening portion where the light emitted by the first light-emitting portion transmits through, and the second opening portions 122 and 124 correspond to the second opening portion where the light emitted by the second light-emitting portion transmits through.

The light-shielding layer 120 is formed of an organic material or a metal material. In the case of using an organic material (e.g. resin material) for the light-shielding layer 120, influence on the emitter 110 can be minimized when processing the light-shielding layer 120. In the case of using a metal material (e.g. metal material) for the light-shielding layer 120, on the other hand, a further improvement of the light-shielding performance by the light-shielding layer 120 against the light emitted by the emitter 110 can be expected.

Color filters 131 to 134 are disposed at positions corresponding to the emitters 111 to 114. The color filters 131 to 134 are constituted of a plurality of types of emission colors. For example, the color filters 131 to 134 are arranged to be a RGB configuration, whereby a full color display becomes possible in the light-emitting element 100. For a pair of the first light-emitting portion 101 and the second light-emitting portion 102, the color filters 131 and 132, which have the same emission color, are disposed. In the same manner, for the pair of the first light-emitting portion 103 and the second light-emitting portion 104, the color filters 133 and 134, which have the same emission color, are disposed. In the case of attaining emission color of RGB in the light-emitting element 100 illustrated in FIGS. 1A and 1B, the first light-emitting portion and the second light-emitting portion are disposed for a pixel of each color. When the image is generated using the light-emitting element 100, the first light-emitting portion and the second light-emitting portion may be disposed only for a pixel to emit a color of light which has a particular influence on an image quality of the image to be generated. In other words, in a pixel which emits a specific color of light, a plurality of opening portions are disposed by forming the first light-emitting portion and the second light-emitting portion, and in a pixel which emits a color of light that is different from the above pixel, only one opening portion, where the light of the light-emitting portion transmit through, is disposed. According to this pixel configuration, the pixel size in the light-emitting element 100 can be decreased. The sizes and/or shapes of the color filters 131 and 132 may be configured to be the same. The color filters 133 and 134, and a set of color filters of other pixels, can also be configured in the same manner. By the color filters having the same sizes and/or shapes, the color filters can be manufactured more easily. This is the same for the following embodiments as well.

In the light-emitting element 100, the color filters 131 and 132 are disposed so as to not overlap with both of the first opening portion 121 and the second opening portion 122. In other words, the color filter 131 is disposed to overlap with the first opening portion 121 which is formed to correspond to the emitter 111, but not to overlap with the second opening portion 122. In the same manner, the color filter 132 is disposed to overlap with the second opening portion 122 which is formed to correspond to the emitter 112, but not to overlap with the first opening portion 121. This arrangement makes it easy to process the color filters, since each color filter can be processed to align with one opening portion corresponding to this color filter, without being influenced by the other opening portions. However, the color filters may be disposed such that one color filter overlaps with a plurality of opening portions. For example, in the case of disposing one color filter overlapping with two opening portions, the color filter can suppress leaked light from a gap between the two opening portions. Thereby the image quality of the image generated in the image generation using the light-emitting element 100 can be improved. Further, a color filter and an opening portion may be integrally disposed. In this arrangement, the light-shielding layer 120 and the color filters can be formed simultaneously, and an effect of suppressing leaked light from the gap between the color filter and the opening portion can also be expected.

The difference between the first light-emitting portion 101 and the second light-emitting portion 102 in the pixel 140 will be described next. The difference between the first light-emitting portion and the second light-emitting portion is the same for the other pixels 150, 160, 170, 180 and 190. The difference between the first light-emitting portion 101 and the second light-emitting portion 102 is the difference of the opening areas between the first opening portion 121 and the second opening portion 122. The opening area of the second opening portion 122 corresponding to the second light-emitting portion 102 is smaller than the opening area of the first opening portion 121 corresponding to the first light-emitting portion 101. Because of this configuration, in the case where the amount of light emitted by the emitter 111 and that by the emitter 112 are the same, the brightness of the light outputted from the second light-emitting portion 102 can be made to be lower than the brightness of the light outputted from the first light-emitting portion 101 using the first opening portion 121 and the second opening portion 122.

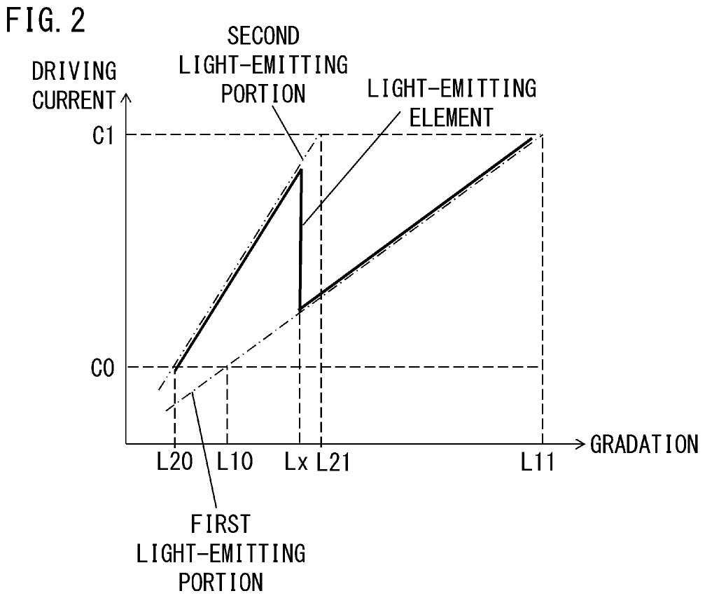

Driving of the first light-emitting portion 101 and the second light-emitting portion 102 will be described next. FIG. 2 is a graph depicting a relationship between the gradation outputted by each light-emitting portion and the driving current. In the graph, the broken line indicates a characteristic that is acquired in the case where the first light-emitting portion 101 or the second light-emitting portion 102 is driven alone, and the solid line indicates the characteristic that is acquired in the case where the light-emitting element 100 is driven.

An organic EL element has a characteristic that tone changes in a region where the driving current is low. The reason why the tone changes will be described later. In the graph in FIG. 2, C0 is the lower limit of the driving current with which the generation of the tone change is allowable in the light-emitting element 100, and C1 is the maximum value of the driving current that can be applied to the light-emitting element 100.

The gradation range of the first light-emitting portion 101 is a range from L10, where the driving current is C0, to L11 where the driving current is C1. The gradation at L10 or less becomes smaller than at the driving current C0, where unallowable tone change is generated in the light-emitting element 100. Further, the opening area of the second opening portion 22 of the second light-emitting portion 102 is smaller than the opening area of the first opening portion 121 of the first light-emitting portion 101. Therefore, even if the same driving current is applied to the emitter 111 of the first light-emitting portion 101 and the emitter 112 of the second light-emitting portion 102, the gradation range of the second light-emitting portion 102 becomes narrower than the gradation range of the first light-emitting portion 101. In the second light-emitting portion 102, the gradation when the driving current is C0 is L20, and gradation lower than L10, which is the lower limit of the gradation of the first light-emitting portion 101, can be outputted. On the other hand, in the second light-emitting portion 102, the gradation when the driving current is C1 is L21, and this gradation is lower than L11, which is the upper limit of the gradation of the first light-emitting portion 101.

In the driving of the light-emitting element 100, which is indicated by the solid line in the graph, the second light-emitting portion 102 is used for the output on the lower gradation side, and the first light-emitting portion 101 is used for the output on the higher gradation side. Therefore, the light-emitting element 100 can output a wider gradation than the case of driving the first light-emitting portion 101 or the second light-emitting portion 102 alone.

In the graph, the gradation Lx is a gradation at which the driving is switched between the first light-emitting portion 101 and the second light-emitting portion 102. The gradation Lx needs to be between the gradation L10 and the gradation L21. The gradation L21 needs to be higher than the gradation L10. The opening area of the second opening portion 122 is set such that the gradation L10 and the gradation L21 satisfy this relationship. If the gradation L10 and the gradation L21 become the same gradation, the gradation range becomes a range from the gradation L20 to the gradation L11, that is, a range of the gradation which can be outputted becomes maximum. If the difference between the gradation L10 and the gradation L21 is large, on the other hand, the gradation Lx can be smaller than the gradation L21. Therefore as indicated in the graph, it is not necessary to drive the second light-emitting portion 102 at the maximum gradation in the intermediate gradation range, including the gradation Lx which is frequently used, hence deterioration of the emitter 112 of the second light-emitting portion 102 is suppressed, and the lifespan of the light-emitting element 100 can be extended.

The opening area of the second opening portion 122 may also be determined depending on the allowable range of the tone change in the light-emitting element 100. In the case of increasing the gradation range that can be outputted in a state of minimizing the tone change, it is preferable that the opening area of the second opening portion 122 is in a range of at least 0.3 times and not more than 0.6 times of the opening area of the first opening portion 121. In the case where the allowable range of the tone change is less strict, it is preferable that the opening area of the second opening portion 122 is in a range of at least 0.05 times and not more than 0.3 times of the opening area of the first opening portion 121. Thereby the gradation range that can be outputted can be further increased, while suppressing the tone change in the light-emitting element 100 to within the allowable range.

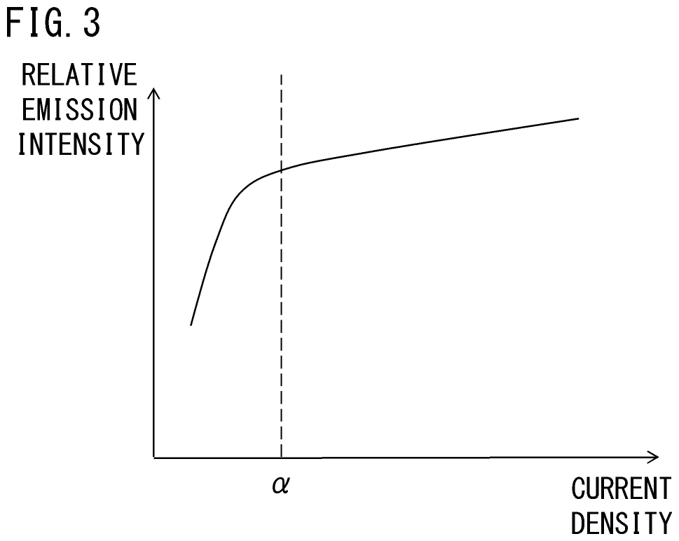

Now the reason why the tone changes in a region where driving current is low in the organic EL element will be described. FIG. 3 is a graph indicating a general relationship between a relative emission intensity of blue components of the light outputted by the organic EL element and the current density thereof. In the graph, the relative emission intensity indicates a ratio of the emission intensity of the blue components of the light outputted by the organic EL element when the emission intensity of the red components of the light outputted by the organic EL element is 1.

As indicated in FIG. 3, in a region where the current density is higher than α, the relative emission intensity changes linearly with respect to the current density, hence adjustment of the brightness by performing correction or the like is easy, and the tone change can be minimized. In a region where the current density is lower than α, on the other hand, the relative emission intensity changes non-linearly, hence adjustment of brightness is more difficult, and suppressing the tone change is therefore more difficult. As a result, in order to minimize the tone change in the organic EL element, driving in a region where the current density is higher than α is necessary. The driving current C0 in the graph in FIG. 2 corresponds to the current density α in the graph in FIG. 3.

According to the light-emitting element 100 of First Embodiment, the opening area of each opening portion in the pixel is set as described above, whereby the multi-gradation of the pixel can be implemented using a structure simpler than conventional light-emitting elements.

### Second Embodiment

A light-emitting element according to Second Embodiment will be described next. In the following description, a composing element the same as First Embodiment is denoted with a same reference sign, and detailed description thereof is omitted.

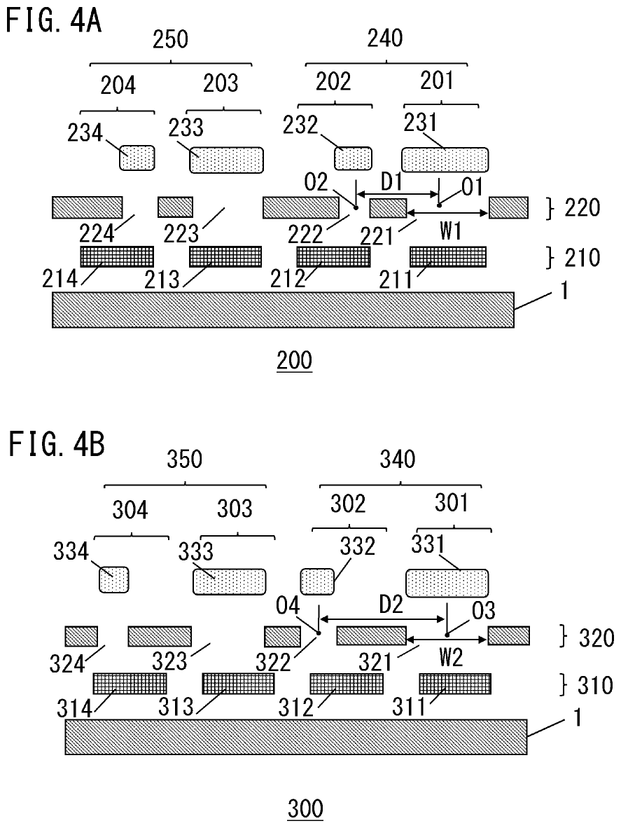

Light-emitting elements according to Second Embodiment will be described with reference to FIGS. 4A and 4B. FIGS. 4A and 4B indicate light-emitting elements 200 and 300 respectively as examples of the light-emitting element of Second Embodiment. The top views of the light-emitting elements 200 and 300 are the same as that of the light-emitting element 100 illustrated in FIGS. 1A and 1B. Pixels 240 and 250, first light-emitting portions 201 and 203, and second light-emitting portions 202 and 204 of the light-emitting element 200 correspond to the pixels 140 and 150, the first light-emitting portions 101 and 103 and the second light-emitting portions 102 and 104 of the light-emitting element 100 respectively. Emitters 211 to 214, a light-shielding layer 220 and color filters 231 to 234 of the light-emitting element 200 correspond to the emitters 111 to 114, the light-shielding layer 120 and the color filters 131 to 134 of the light-emitting element 100 respectively. In the same manner, pixels 340 and 350, first light-emitting portions 301 and 303, and second light-emitting portions 302 and 304 of the light-emitting element 300 correspond to the pixels 140 and 150, the first light-emitting portions 101 and 103, and the second light-emitting portions 102 and 104 of the light-emitting element 100 respectively. Emitters 311 to 314, a light-shielding layer 320 and color filters 331 to 334 of the light-emitting element 300 correspond to the emitters 111 to 114, the light-shielding layer 120, and the color filters 131 to 134 of the light-emitting element 100 respectively.

A difference of the light-emitting elements 200 and 300 from the light-emitting element 100 of First Embodiment is that the light-shielding layers 220 and 320, of which configuration of the opening portion is different from the light-shielding layer 120 of the light-emitting element 100, are disposed in the light-emitting elements 200 and 300. As illustrated in FIGS. 4A and 4B, the configurations of the light-emitting elements 200 and 300 are the same as the light-emitting element 100, except for the configurations of the light-shielding layers 220 and 320.

As illustrated in FIG. 4A, in the light-shielding layer 220, the first light-emitting portion 201 includes a first opening portion 221 where light emitted by the emitter 211 transmits through, and a second opening portion 222 where light emitted by the emitter 212 transmits through. A distance between the first opening portion 221 and the second opening portion 222 is assumed to be a distance D1 between an opening center O1 of the first opening portion 221 and an opening center O2 of the second opening portion 222. In the same manner, as illustrated in FIG. 4B, in the light-shielding layer 320 of the light-emitting element 300, a distance between a first opening portion 321 and a second opening portion 322 is assumed to be a distance D2 between an opening center O3 of the first opening portion 321 and an opening center O4 of the second opening portion 322.

As illustrated in FIG. 4A, compared with the light-shielding layer 120 of the light-emitting element 100 of FIGS. 1A and 1B, the distance D1 between the first opening portion 221 and the second opening portion 222 in the light-shielding layer 220 of the light-emitting element 200 is shorter than the distance between the first opening portion 121 and the second opening portion 122 of the light-emitting element 100. Further, the distance D1 between the first opening portion 221 and the second opening portion 222 is smaller than the opening size W1 of the first opening portion 221. Therefore according to the configuration of the first opening portion 221 and the second opening portion 222 of the light-emitting element 200, the first light-emitting portion 201 and the second light-emitting portion 202 are visually recognized in a more integrated way, hence an improvement of image quality can be expected.

Also as illustrated in FIG. 4B, compared with the light-shielding layer 120 of the light-emitting element 100 of FIGS. 1A and 1B, the distance D2 between the first opening portion 321 and the second opening portion 322 in the light-shielding layer 320 of the light-emitting element 300 is longer than the distance between the first opening portion 121 and the second opening portion 122 of the light-emitting element 100. Further, the distance D2 between the first opening portion 321 and the second opening portion 322 is larger than the opening size W2 of the first opening portion 321. Therefore according to the configuration of the first opening portion 321 and the second opening portion 322 of the light-emitting element 300, leakage of light emitted by the emitter 311 and 312 between the first light-emitting portion 301 and the second light-emitting portion 302 of the light-emitting element 300 can be suppressed. As a result, according to the light-emitting element 300, gradation can be more accurately expressed, hence an improvement of image quality can be expected.

Also as illustrated in FIGS. 4A and 4B, compared with the pixel 140 of the light-emitting element 100, the opening centers O2 and O4 of the second opening portions 222 and 322 are shifted in the pixel 240 of the light-emitting element 200 and the pixel 340 of the light-emitting element 300. However, the emitters 211, 212, 311 and 312 and the color filters 231, 232, 331 and 332 are not shifted. In the case of this configuration of the light-emitting elements 200 and 300, the emitters 211, 212, 311 and 312 and the color filters 231, 232, 331 and 332 can be formed more easily. The other pixels of the light-emitting elements 200 and 300 can also be configured in the same way as the pixels 240 and 340.

On the other hand, in the pixel 240 of the light-emitting element 200 and the pixel 340 of the light-emitting element 300, the emitters 211 and 311 and the color filters 231 and 331 of the first light-emitting portions 201 and 301 may be shifted in accordance with the positions of the first opening portions 221 and 321 respectively. If the light-emitting elements 200 and 300 have this configuration, the emitters 211 and 311 and the color filters 231 and 331 can be disposed at optically optimum positions. The other pixels of the light-emitting elements 200 and 300 can also be configured in the same way as the pixels 240 and 340.

### Third Embodiment

A light-emitting element according to Third Embodiment will be described next. In the following description, a composing element the same as the above embodiments is denoted with a same reference sign, and detailed description thereof will be omitted.

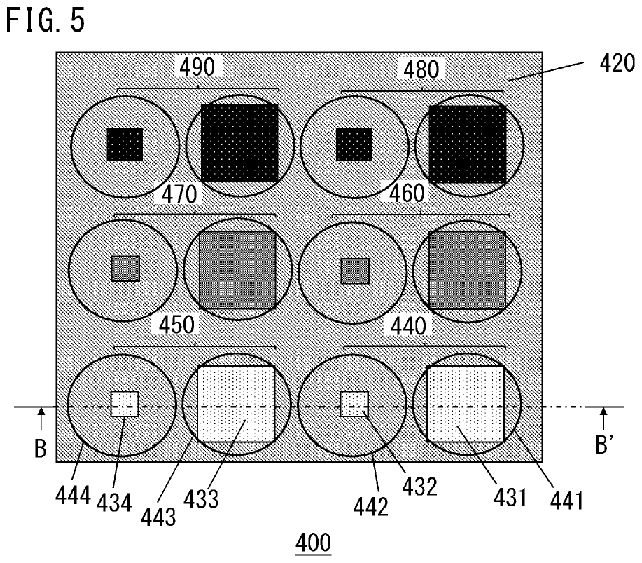

The light-emitting element according to Third Embodiment will be described with reference to FIG. 5. FIG. 5 indicates a light-emitting element 400, which is an example of the light-emitting element of Third Embodiment. The light-emitting element 400 includes pixels 440, 450, 460, 470, 480 and 490. The pixels 440 and 450, the first light-emitting portions 401 and 403, and the second light-emitting portions 402 and 404 of the light-emitting element 400 correspond to the pixels 140 and 150, the first light-emitting portions 101 and 103 and the second light-emitting portions 102 and 104 of the light-emitting element 100 respectively. Emitters 411 to 414, a light-shielding layer 420 and color filters 431 to 434 of the light-emitting element 400 correspond to the emitters 111 to 114, the light-shielding layer 120 and the color filters 131 to 134 of the light-emitting element 100 respectively.

A difference of the light-emitting element 400 from the above-mentioned light-emitting elements 100, 200 and 300 is that micro-lenses 441, 442, 443 and 444 are disposed on the color filters 431, 432, 433 and 434 respectively in the pixels 440 and 450 of the light-emitting element 400. The configurations of the pixels 460, 470, 480 and 490 of the light-emitting element 400 are the same as the pixels 440 and 450. The configuration of each composing element of the light-emitting element 400, other than the micro-lenses, is the same as the configuration of each composing element of the light-emitting element 100. The micro-lenses 441 and 443 correspond to the first micro-lens, and the micro-lenses 442 and 444 correspond to the second micro-lens which has the same shape as the first micro-lens.

In the pixel 440 of the light-emitting element 400, the micro-lenses 441 and 442 are micro-lenses disposed on the first light-emitting portion 401 and the second light-emitting portion 402 respectively. By disposing the micro-lens 441, light transmitted through the first opening portion 421 can be collected. In the same manner, by disposing the micro-lens 442, light transmitted through the second opening portion 422 can be collected. Thereby in the case of the light-emitting element 400, implementing higher brightness in the pixels 440, 450, 460, 470, 480 and 490 can be expected.

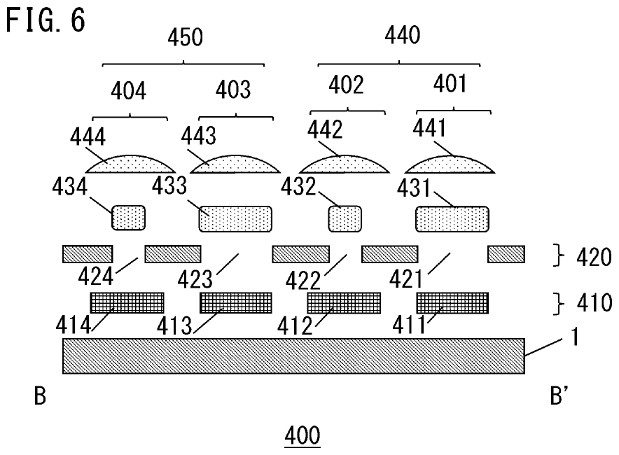

An arrangement example of the micro-lenses of the light-emitting element according to Third Embodiment will be described next with reference to the drawings. FIG. 6 is a cross-sectional view of the light-emitting element 400 sectioned at the B-B′ line in FIG. 5. In the light-emitting element 400, micro-lenses are disposed on the light-emitting element 100 of the First Embodiment.

In FIG. 6, in the light-emitting element 400, the emitters 411, 412, 413 and 414 are disposed at equal intervals. The center of the emitter 411 and the center of the first opening portion 421 match. In the same manner, the center of the emitter 412 and the center of the second opening portion 422 match. The relationships between the emitter 413 and the first opening portion 423 and between the emitter 414 and the second opening portion 424 are also the same. The center of the micro-lens 441 is disposed to match with the center of the first opening portion 421. The relationships between the micro-lens 442 and the second opening portion 422, between the micro-lens 443 and the first opening portion 423, and between the micro-lens 444 and the second opening portion 424 are also the same.

In the example in FIG. 6, the micro-lenses 441 to 444 having the same shape are disposed at equal intervals. Because of this arrangement of the micro-lenses, the micro-lenses 441 to 444 can be easily processed, and dispersion of the shapes of the micro-lenses 441 to 444 can be minimized. The shapes of the micro-lenses 441 to 444 may be different from each other, so as to match with the corresponding shapes of the opening portions, for example. By configuring the micro-lenses in this way, the optical structure of the first light-emitting portions 401 and 403 and the second light-emitting portions 402 and 404 can be optimized respectively.

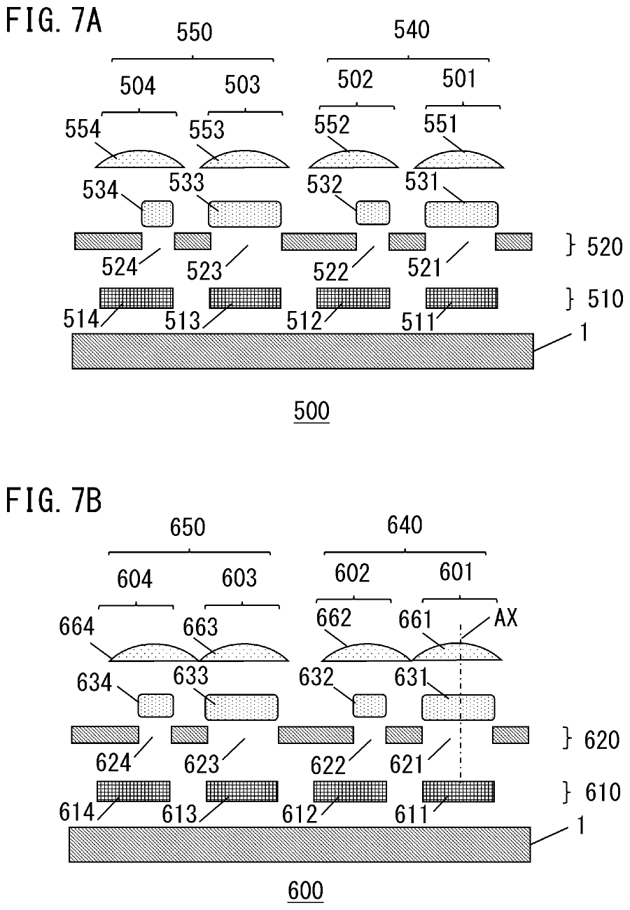

FIG. 7A indicates a light-emitting element 500, which is an example of a light-emitting element of which arrangement of the micro-lenses is different from the light-emitting element 400. Pixels 540 and 550, first light-emitting portions 501 and 503, and second light-emitting portions 502 and 504 of the light-emitting element 500 correspond to the pixels 440 and 450, the first light-emitting portions 401 and 403, and the second light-emitting portions 402 and 404 of the light-emitting element 400 respectively. Emitters 511 to 514, a light-shielding layer 520, and color filters 531 to 534 of the light-emitting element 500 correspond to the emitters 411 to 414, the light-shielding layer 420, and the color filters 431 to 434 of the light-emitting element 400 respectively.

In the light-emitting element 500 illustrated in FIG. 7A, the color filters 531 to 534 are disposed at equal intervals. In the same manners, the micro-lenses 541 to 544 are disposed at equal intervals. Since the color filters and the micro-lenses are disposed like this, the micro-lenses 541 to 544 are cyclically disposed. Thereby processing and arrangement of the micro-lenses 541 to 544 become easier, and minimizing dispersion of the shapes of the micro-lenses 541 to 544 can be expected.

FIG. 7B indicates a light-emitting element 600, which is an example of a light-emitting element of which arrangement of the micro-lenses is different from the light-emitting element 400. Pixels 640 and 650, first light-emitting portions 601 and 603, and second light-emitting portions 602 and 604 of the light-emitting element 600 correspond to the pixels 440 and 450, the first light-emitting portions 401 and 403, and the second light-emitting portions 402 and 404 of the light-emitting element 400 respectively. Emitters 611 to 614, a light-shielding layer 620 and color filters 631 to 634 of the light-emitting element 600 correspond to the emitters 411 to 414, the light-shielding layer 420, and the color filters 431 to 434 of the light-emitting element 400 respectively.

In the light-emitting element 600 illustrated in FIG. 7B, as the first light-emitting portion 601 of the pixel 640 indicates, the center of the color filter 631, the center of the micro-lens 661 and the opening center of the first opening portion 621 are on the axis AX. If the center of the color filter 631, the center of the micro-lens 661 and the opening center of the first opening portion 621 are aligned like this, the distance between the micro-lens 661 and the micro-lens 662 becomes short. Thereby the first light-emitting portion 601 and the second light-emitting portion 602 can be visually recognized in a more integrated way. Instead of disposing the micro-lenses 661 and 662, one micro-lens may be disposed for the first light-emitting portion 601 and the second light-emitting portion 602. Thereby a number of micro-lenses required in producing the light-emitting element 600 can be reduced.

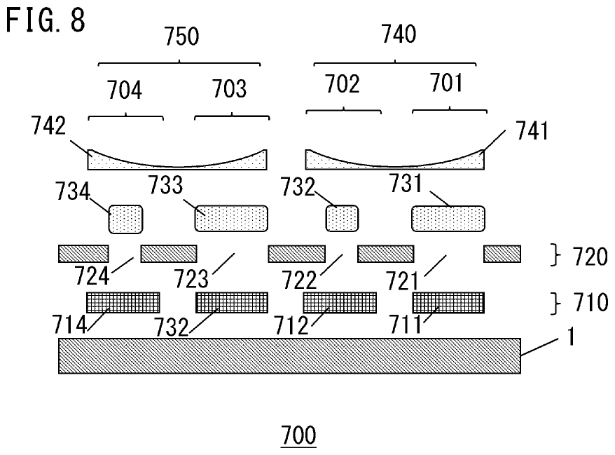

FIG. 8 indicates a light-emitting element 700, which is an example of a light-emitting element of which arrangement of the micro-lenses is different from the light-emitting element 400. Pixels 740 and 750, first light-emitting portions 701 and 703 and second light-emitting portions 702 and 704 of the light-emitting element 700 correspond to the pixels 440 and 450, the first light-emitting portions 401 and 403, and the second light-emitting portions 402 and 404 of the light-emitting element 400 respectively. Emitters 711 to 714, a light-shielding layer 720 and color filters 731 to 734 of the light-emitting element 700 correspond to the emitters 411 to 414, the light-shielding layer 420, and the color filters 431 to 434 of the light-emitting element 400 respectively.

As illustrated in FIG. 8, in the light-emitting element 700, a concave lens 741 is disposed in the pixel 740, instead of the micro-lenses 441 and 442 in the light-emitting element 400. In the same manner, a concave lens 742 is disposed in the pixel 750, instead of the micro-lenses 443 and 444 of the light-emitting element 400. By using the concave lenses 741 and 742 as the micro-lenses like this, the lights emitted by the first light-emitting portion 701 and the second light-emitting portion 702 in the pixel 740 travels on the extended line of the boundary of these light-emitting portions. Thereby the first light-emitting portion 701 and the second light-emitting portion 702 are visually recognized in a more integrated way as a single light-emitting portion. Instead of the concave lenses 741 and 742, a lens having a shape other than a concave surface, such as a prism shape, may be used.

[Structure of an Organic Light-Emitting Element] In the present embodiment the organic light-emitting element is provided by forming an insulating layer, a first electrode, an organic compound layer and a second electrode, on a substrate. A protective layer, a color filter, a microlens and so forth may be provided on a cathode. In a case where a color filter is provided, a planarization layer may be provided between the color filter and the protective layer. The planarization layer can be for instance made up of an acrylic resin. The same is true in a case where the planarization layer is provided between the color filter and the microlens.

[Substrate] At least one material selected from quartz, glass, silicon, resins and metals can be used as the material for the substrate that makes up the organic light-emitting element. Switching elements such as transistors and wiring may be provided on the substrate, and an insulating layer may be provided on the foregoing. Any material can be used as the insulating layer so long as a contact hole can be formed between the insulating layer and the first electrode, and insulation from unconnected wiring can be ensured, so that wiring can be formed between the first electrode and the insulating layer. For instance a resin such as a polyimide, or silicon oxide or silicon nitride can be used herein.

[Electrodes] A pair of electrodes can be used as the electrodes of the organic light-emitting element. The pair of electrodes may be an anode and a cathode. In a case where an electric field is applied in the direction in which the organic light-emitting element emits light, the electrode of higher potential is the anode, and the other electrode is the cathode. Stated otherwise, the electrode that supplies holes to the light-emitting layer is the anode, and the electrode that supplies electrons is the cathode.

A material having a work function as large as possible is preferable herein as a constituent material of the anode. For instance single metals such as gold, platinum, silver, copper, nickel, palladium, cobalt, selenium, vanadium or tungsten, and mixtures containing the foregoing metals, can be used in the anode. Alternatively, alloys obtained by combining these single metals, or metal oxides such as tin oxide, zinc oxide, indium oxide, indium tin oxide (ITO) or indium zinc oxide, may be used in the anode. Conductive polymers such as polyaniline, polypyrrole and polythiophene can also be used in the anode.

Any of the foregoing electrode materials may be used singly; alternatively, two or more materials may be used concomitantly. The anode may be made up of a single layer, or may be made up of a plurality of layers.

In a case where an electrode of the organic light-emitting element is configured in the form of a reflective electrode, the electrode material can be for instance chromium, aluminum, silver, titanium, tungsten, molybdenum, or alloys or layered bodies of the foregoing. The above materials can also function as a reflective film not having a role as an electrode. In a case where an electrode of the organic light-emitting element is configured in the form of a transparent electrode, for instance an oxide transparent conductive layer of for instance indium tin oxide (ITO) or indium zinc oxide can be used, although not particularly limited thereto, as the electrode material. The electrodes may be formed by photolithography.

A material having a small work function may be a constituent material of the cathode. For instance alkali metals such as lithium, alkaline earth metals such as calcium, single metals such as aluminum, titanium, manganese, silver, lead or chromium, and mixtures of the foregoing, may be used herein. Alternatively, alloys obtained by combining these single metals can also be used. For instance magnesium-silver, aluminum-lithium, aluminum-magnesium, silver-copper or zinc-silver can be used. Metal oxides such as indium tin oxide (ITO) can also be used. These electrode materials may be used singly as one type, or two or more types can be used concomitantly. Also, the cathode may have a single-layer structure or a multilayer structure. Silver is preferably used among the foregoing, and more preferably a silver alloy, in order to reduce silver aggregation. Any alloy ratio can be adopted, so long as silver aggregation can be reduced. A ratio silver: other metal may be for instance 1:1, or 3:1.

Although not particularly limited thereto, the cathode may be a top emission element that utilizes an oxide conductive layer of ITO or the like, or may be a bottom emission element that utilizes a reflective electrode of aluminum (Al) or the like. The method for forming the cathode is not particularly limited, but more preferably for instance a DC or AC sputtering method is resorted to, since in that case film coverage is good and resistance can be readily lowered.

[Pixel Separation Layer] The pixel separation layer of the organic light-emitting element is formed out of a silicon nitride (SiN) film, a silicon oxynitride (SiON) film, or a silicon oxide (SiO) film, in turn having been formed by chemical vapor deposition (CVD). In order to increase the in-plane resistance of the organic compound layer, preferably the thickness of the organic compound layer that is formed, particularly a hole transport layer, is set to be small at the side walls of the pixel separation layer. Specifically, the side walls can be formed to be thin by increasing vignetting at the time of deposition, through an increase of the taper angle of the side walls of the pixel separation layer and/or an increase of the thickness of the pixel separation layer.

On the other hand, it is preferable to adjust the side wall taper angle of the pixel separation layer and the thickness of the pixel separation layer so that no voids are formed in the protective layer that is formed on the pixel separation layer. The occurrence of defects in the protective layer can be reduced by virtue of the fact that no voids are formed in the protective layer. Since the occurrence of defects in the protective layer is thus reduced, it becomes possible to reduce loss of reliability for instance in terms of the occurrence of dark spots or defective conduction in the second electrode.

The present embodiment allows effectively suppressing leakage of charge to adjacent pixels even when the taper angle of the side walls of the pixel separation layer is not sharp. Studies by the inventors of the present application have revealed that leakage of charge to adjacent pixels can be sufficiently reduced if the taper angle lies in the range at least 60 degrees and not more than 90 degrees. The thickness of the pixel separation layer is preferably at least 10 nm and not more than 150 nm. A similar effect can be achieved also in a configuration having only a pixel electrode lacking a pixel separation layer. In this case, however, it is preferable to set the film thickness of the pixel electrode to be half or less the thickness the organic layer, or to impart forward taper at the ends of the pixel electrode, at a taper angle smaller than 60 degrees, since short circuits of the organic light-emitting element can be reduced thereby.

[Organic Compound Layer] The organic compound layer of the organic light-emitting element may be formed out of a single layer or multiple layers. In a case where the organic compound layer has multiple layers, these may be referred to as a hole injection layer, a hole transport layer, an electron blocking layer, a light-emitting layer, a hole blocking layer, an electron transport layer or an electron injection layer, depending on the function of the layer. The organic compound layer is mainly made up of organic compounds, but may contain inorganic atoms and inorganic compounds. For instance the organic compound layer may have copper, lithium, magnesium, aluminum, iridium, platinum, molybdenum or zinc. The organic compound layer may be disposed between the first electrode and the second electrode, and may be disposed in contact with the first electrode and the second electrode.

[Protective Layer] In the organic light-emitting element of the present embodiment, a protective layer may be provided on the second electrode. For instance, intrusion of water or the like into the organic compound layer can be reduced, and the occurrence of display defects also reduced, by bonding a glass provided with a moisture absorbent onto the second electrode. As another embodiment, a passivation film of for instance silicon nitride may be provided on the cathode, to reduce intrusion of water or the like into the organic compound layer. For instance, formation of the cathode may be followed by conveyance to another chamber, without breaking vacuum, whereupon a protective layer may be formed through formation of a silicon nitride film having a thickness of 2 μm by CVD. The protective layer may be provided by atomic deposition (ALD), after film formation by CVD. The material of the film formed by ALD is not limited, but may be for instance silicon nitride, silicon oxide or aluminum oxide. Silicon nitride may be further formed, by CVD, on the film having been formed by ALD. The film formed by ALD may be thinner than the film formed by CVD. Specifically, the thickness of the film formed by ALD may be 50% or less, or 10% or less.

[Color Filter] A color filter may be provided on the protective layer of the organic light-emitting element of the present embodiment. For instance a color filter having factored therein the size of the organic light-emitting element may be provided on another substrate, followed by affixing to a substrate having the organic light-emitting element provided thereon; alternatively, a color filter may be patterned by photolithography on the protective layer illustrated above. The color filter may be made up of a polymer.

[Planarization Layer] The organic light-emitting element of the present embodiment may have a planarization layer between the color filter and the protective layer. The planarization layer is provided for the purpose of reducing underlying layer unevenness. The planarization layer may be referred to as a resin layer in a case where the purpose of the planarization layer is not limited. The planarization layer may be made up of an organic compound, which may be a low-molecular or high-molecular compound, preferably a high-molecular compound.

The planarization layer may be provided above and below the color filter, and the constituent materials of the respective planarization layers may be identical or dissimilar. Concrete examples include polyvinylcarbazole resins, polycarbonate resins, polyester resins, ABS resins, acrylic resins, polyimide resins, phenolic resins, epoxy resins, silicone resins and urea resins.

[Microlens] The organic light-emitting element may have an optical member such as a microlens, on the light exit side. The microlens may be made up of for instance an acrylic resin or an epoxy resin. The purpose of the microlens may be to increase the amount of light extracted from the organic light-emitting element, and to control the direction of the extracted light. The microlens may have a hemispherical shape. In a case where the microlens has a hemispherical shape, then from among tangent lines that are in contact with the hemisphere there is a tangent line that is parallel to the insulating layer, such that the point of contact between that tangent line and the hemisphere is the apex of the microlens. The apex of the microlens can be established similarly in any cross section. That is, among tangent lines that are in contact with a semicircle of the microlens in a sectional view, there is a tangent line that is parallel to the insulating layer, such that the point of contact between that tangent line and the semicircle is the apex of the microlens.

A midpoint of the microlens can also be defined. Given a hypothetical line segment from the end point of an arc shape to the end point of another arc shape, in a cross section of the microlens, the midpoint of that line segment can be referred to as the midpoint of the microlens. The cross section for discriminating the apex and the midpoint may be a cross section that is perpendicular to the insulating layer.

The microlens has a first surface with a bulge and a second surface on the reverse side from that of the first surface. Preferably, the second surface is disposed closer to a functional layer than the first surface. In adopting such a configuration, the microlens must be formed the organic light-emitting element. In a case where the functional layer is an organic layer, it is preferable to avoid high-temperature processes in the manufacturing process. If a configuration is adopted in which the second surface is disposed closer to the functional layer than the first surface, the glass transition temperatures of all the organic compounds that make up the organic layer are preferably 100° C. or higher, and more preferably 130° C. or higher.

[Counter Substrate] The organic light-emitting element of the present embodiment may have a counter substrate on the planarization layer. The counter substrate is so called because it is provided at a position corresponding to the above-described substrate. The constituent material of the counter substrate may be the same as that of the substrate described above. The counter substrate can be used as the second substrate in a case where the substrate described above is used as the first substrate.

[Organic Layer] Each organic compound layer (hole injection layer, hole transport layer, electron blocking layer, light-emitting layer, hole blocking layer, electron transport layer, electron injection layer and so forth) that makes up the organic light-emitting element of the present embodiment is formed in accordance with one of the methods illustrated below.

A dry process such as vacuum deposition, ionization deposition, sputtering, plasma or the like can be used for the organic compound layers that make up the organic light-emitting element of the present embodiment. A wet process in which a layer is formed through dissolution in an appropriate solvent, relying on a known coating method (for instance spin coating, dipping, casting, LB film deposition to inkjet.) can resorted to instead of a dry process.

When a layer is formed for instance by vacuum deposition or by solution coating, crystallization or the like is unlikelier occur; this translates into superior stability over time. In a case where a film is formed in accordance with a coating method, the film can be formed by being combined with an appropriate binder resin.

Examples of binder resins include, although not limited to, polyvinylcarbazole resins, polycarbonate resins, polyester resins, ABS resins, acrylic resins, polyimide resins, phenolic resins, epoxy resins, silicone resins and urea resins. These binder resins may be used singly as one type, in the form of homopolymers or copolymers; alternatively, two or more types of binder resin may be used in the form of mixtures. Additives such as known plasticizers, antioxidants and ultraviolet absorbers may be further used concomitantly, as needed.

[Pixel Circuit] A light-emitting device having the organic light-emitting element of the present embodiment may have pixel circuits connected to respective organic light-emitting elements. The pixel circuits may be of active matrix type, and may control independently emission of light by the first organic light-emitting element and the second organic light-emitting element. Active matrix circuits may be voltage-programmed or current-programmed. A drive circuit has a pixel circuit for each pixel. Each pixel circuit may have an organic light-emitting element, a transistor that controls the emission luminance of the organic light-emitting element, a transistor that controls emission timing, a capacitor which holds the gate voltage of the transistor that controls emission luminance, and a transistor for connection to GND bypassing the light-emitting element.

The light-emitting device has a display area and a peripheral area disposed around the display area. The display area has pixel circuits, and the peripheral area has a display control circuit. The mobility of the transistors that make up the pixel circuits may be lower than the mobility of the transistors that make up the display control circuit. The slope of the current-voltage characteristic of the transistors that make up the pixel circuits may be gentler than the slope of the current-voltage characteristic of the transistors that make up the display control circuit. The slope of the current-voltage characteristics can be measured on the basis of a so-called Vg-Ig characteristic. The transistors that make up the pixel circuits are connected to light-emitting elements such as the first organic light-emitting element.

[Pixels] The organic light-emitting element of the present embodiment has a plurality of pixels. The pixels have sub-pixels that emit mutually different colors. The sub-pixels may have for instance respective RGB emission colors. The pixels emit light in a pixel opening region. This region is the same as the first region. The aperture diameter of the pixel openings may be 15 μm or smaller, and may be 5 μm or larger. More specifically, the aperture diameter of the pixel openings may be for instance 11 μm, or 9.5 μm, or 7.4 μm, or 6.4 μm. The spacing between sub-pixels may be 10 μm or smaller, specifically 8 μm, or 7.4 μm, or 6.4 μm.

The pixels can have any known arrangement in a plan view. For instance, the pixel layout may be a stripe arrangement, a delta arrangement, a penile arrangement or a Bayer arrangement. The shape of the sub-pixels in a plan view may be any known shape. For instance, the sub-pixel shape may be for instance quadrangular, such as rectangular or rhomboidal, or may be hexagonal. Needless to say, the shape of the sub-pixels is not an exact shape, and a shape close to that a of rectangle falls under a rectangular shape. Sub-pixel shapes and pixel arrays can be combined with each other.

[Use of the Organic Light-Emitting Element] The organic light-emitting element according to the present embodiment can be used as a constituent member of a display device or of a lighting device. Other uses of the organic light-emitting element include exposure light sources for electrophotographic image forming apparatuses, backlights for liquid crystal display devices, and light-emitting devices having color filters, in white light sources.

The display device may be an image information processing device having an image input unit for input of image information, for instance from an area CCD, a linear CCD or a memory card, and an information processing unit for processing inputted information, such that an inputted image is displayed on a display unit.

A display unit of an imaging device or of an inkjet printer may have a touch panel function. The driving scheme of this touch panel function may be an infrared scheme, a capacitive scheme, a resistive film scheme or an electromagnetic induction scheme, and is not particularly limited. The display device may also be used in a display unit of a multi-function printer.

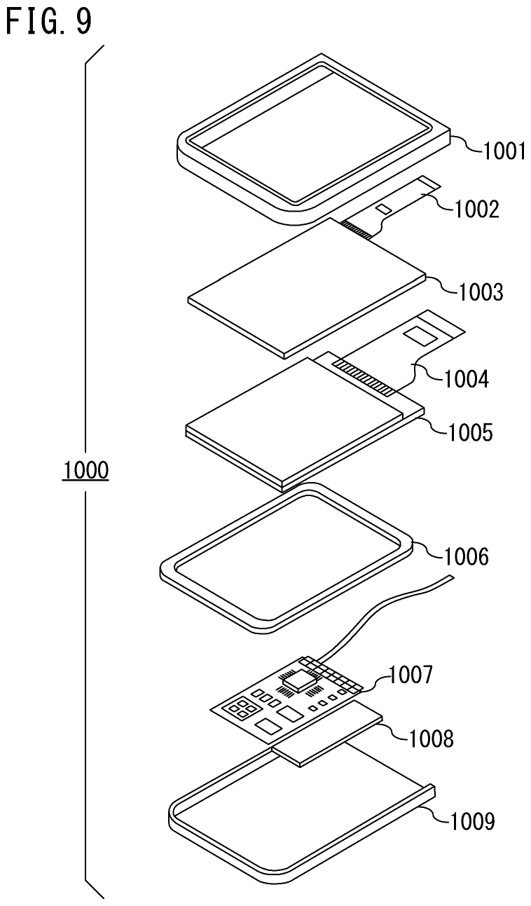

Next, FIG. 9 illustrates a schematic diagram depicting an example of a display device having an organic light-emitting element according to the present embodiment. A display device 1000 may have a touch panel 1003, a display panel 1005, a frame 1006, a circuit board 1007 and a battery 1008, between an upper cover 1001 and a lower cover 1009. The touch panel 1003 and the display panel 1005 are connected to flexible printed circuits FPCs 1002, 1004. Transistors are printed on the circuit board 1007. The battery 1008 may be omitted if the display device is not a portable device; even if the display device is a portable device, the battery 1008 my be provided at a different position.

The display device 1000 may have red, green and blue color filters. The color filters may be disposed in a delta arrangement of the above red, green and blue. The display device 1000 may be used as a display unit of a mobile terminal. In that case the display device 1000 may have both a display function and an operation function. Mobile terminals include mobile phones such as smartphones, tablets and head-mounted displays.

The display device 1000 may be used in a display unit of an imaging device that has an optical unit having a plurality of lenses, and that has an imaging element which receives light having passed through the optical unit. The imaging device may have a display unit that displays information acquired by the imaging element. The display unit may be a display unit exposed outside the imaging device, or may be a display unit disposed within a viewfinder. The imaging device may be a digital camera or a digital video camera.

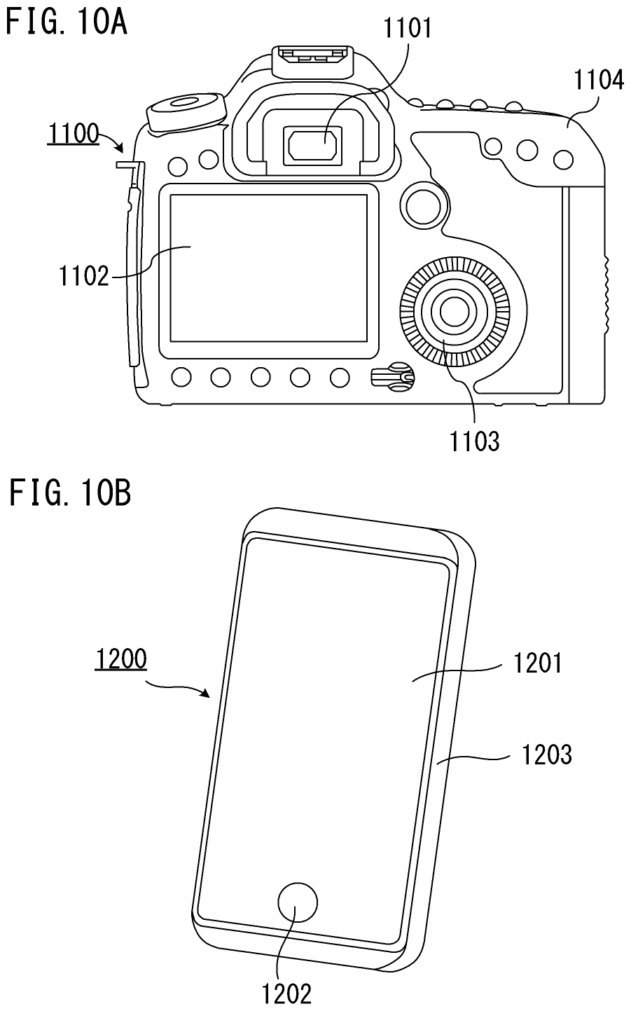

Next, FIG. 10A illustrates a schematic diagram depicting an example of an imaging device having the organic light-emitting element according to the present embodiment. An imaging device 1100 may have a viewfinder 1101, a rear display 1102, an operation unit 1103 and a housing 1104. The viewfinder 1101 may have the display device according to the present embodiment. In that case the display device may display not only an image to be captured, but also for instance environment information and imaging instructions. The environment information may include for instance external light intensity, external light orientation, the moving speed of a subject, and the chance of the subject being blocked by an obstacle.

The timing suitable for imaging is short, and hence information should be displayed as soon as possible. It is therefore preferable to configure the display device so as to have high response speed, using the organic light-emitting element of the present embodiment. A display device that utilizes the organic light-emitting element can be utilized more suitably than these devices or liquid crystal display devices, where high display speed is required.

The imaging device 1100 has an optical unit, not shown. The optical unit has a plurality of lenses, and forms an image on an imaging element accommodated in the housing 1104. The lenses can be focused through adjustment of the relative positions thereof. This operation can also be performed automatically. The imaging device may be referred to as a photoelectric conversion device. The photoelectric conversion device can encompass, as an imaging method other than sequential imaging, a method that involves detecting a difference relative to a previous image, and a method that involves cutting out part of a recorded image.

FIG. 10B is a schematic diagram illustrating an example of an electronic device having the organic light-emitting element according to the present embodiment. An electronic device 1200 includes a display unit 1201, an operation unit 1202, and a housing 1203. The housing 1203 may have a circuit, a printed board having the circuit, a battery, and a communication unit. The operation unit 1202 may be a button, or a touch panel-type reaction unit. The operation unit may be a biometric recognition unit which for instance performs unlocking upon recognition of a fingerprint. The electronic device having a communication unit can also be referred to as a communication device. The electronic device 1200 may further have a camera function, by being provided with a lens and an imaging element. Images captured by way of the camera function are displayed on the display unit. Examples of the electronic device include smartphones and notebook computers.

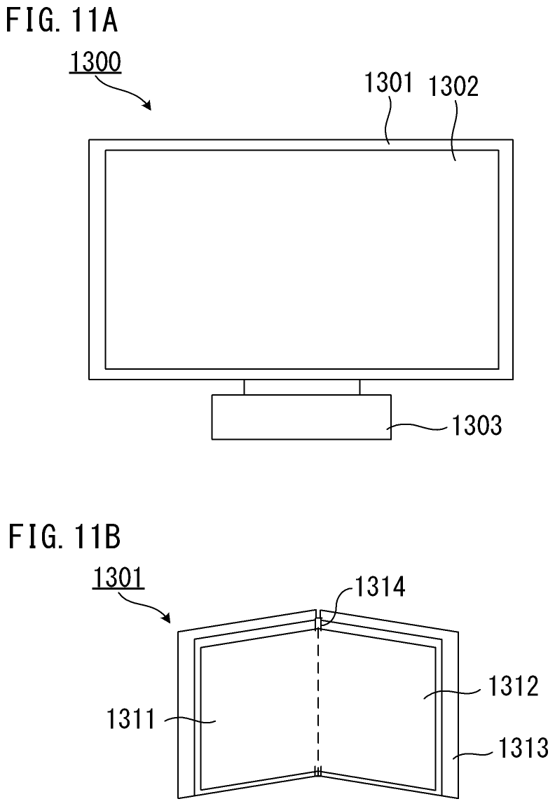

Next, FIG. 11A illustrates a schematic diagram depicting an example of a display device having the organic light-emitting element according to the present embodiment. FIG. 11A illustrates a display device 1300 such as a television monitor or PC monitor. The display device 1300 has a frame 1301 and a display unit 1302. The display unit 1302 may use the organic light-emitting element according to the present embodiment. The display device 1300 also has the frame 1301 and a base 1303 that supports the display unit 1302. The form of the base 1303 is not limited to the form in FIG. 11A. The lower side of the frame 1301 may also double as the base. The frame 1301 and the display unit 1302 may be curved. The radius of curvature of the foregoing may be at least 5000 mm and not more than 6000 mm.

FIG. 11B is a schematic diagram illustrating another example of a display device having the organic light-emitting element according to the present embodiment. A display device 1310 in FIG. 11B is a so-called foldable display device, configured to be foldable. The display device 1310 has a first display unit 1311, a second display unit 1312, a housing 1313 and a folding point 1314. The first display unit 1311 and the second display unit 1312 may have the organic light-emitting element according to the present embodiment. The first display unit 1311 and the second display unit 1312 may be one seamless display device. The first display unit 1311 and the second display unit 1312 can be separated at the folding point. The first display unit 1311 and the second display unit 1312 may display different images; alternatively, the first display unit and the second display unit may display one image.

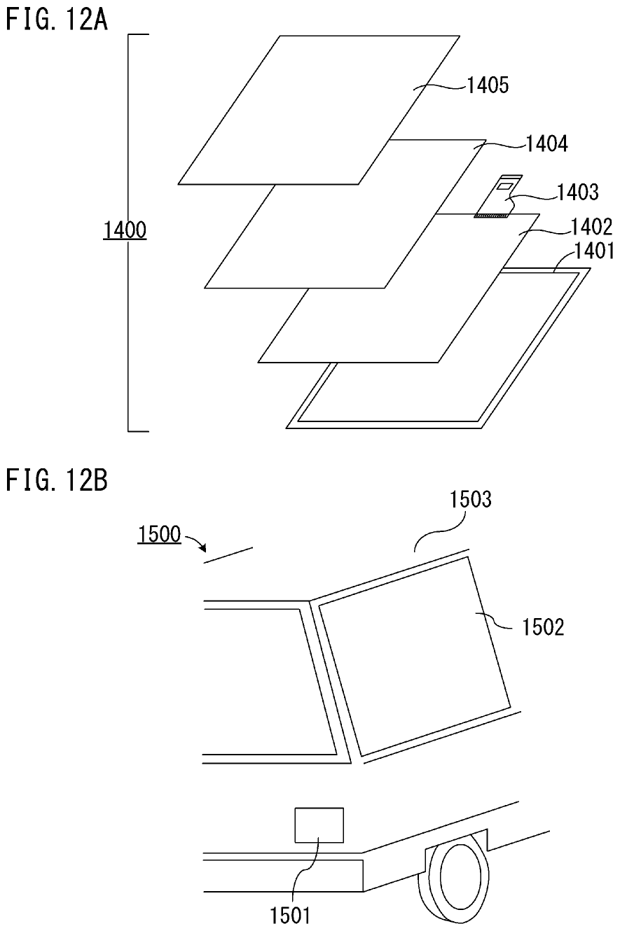

FIG. 12A illustrates next a schematic diagram depicting an example of a lighting device having the organic light-emitting element according to the present embodiment. A lighting device 1400 may have a housing 1401, a light source 1402, a circuit board 1403, an optical film 1404 and a light-diffusing part 1405. The light source has the organic light-emitting element according to the present embodiment. The optical film may be a filter that enhances the color rendering of the light source. The light-diffusing part allows effectively diffusing light from the light source, and allows delivering light over a wide area, for instance in exterior decorative lighting. The optical filter and the light-diffusing part may be provided on the light exit side of the lighting device. A cover may be provided on the outermost part, as the case may require.

The lighting device 1400 is for instance a device for indoor illumination. The lighting device may emit white, daylight white, or other colors from blue to red. The lighting device may have a light control circuit for controlling light having the foregoing emission colors. The lighting device 1400 may have the organic light-emitting element according to the present embodiment, and a power supply circuit connected thereto. The power supply circuit is a circuit that converts AC voltage to DC voltage. White denotes herein a color with a color temperature of 4200 K, and daylight white denotes a color with a color temperature of 5000 K. The lighting device 1400 may have a color filter. The lighting device 1400 may have a heat dissipation part. The heat dissipation part dumps, out of the device, heat from inside the device; the heat dissipation part may be made up of a metal or of liquid silicone rubber, exhibiting high specific heat.

FIG. 12B is a schematic diagram of an automobile, which is an example of a moving body having the organic light-emitting element according to the present embodiment. The automobile has tail lamps, being an example of a lamp. The automobile 1500 may have a tail lamp 1501, of a form such that the tail lamp is lit up when for instance a braking operation is performed.

The tail lamp 1501 has the organic light-emitting element according to the present embodiment. The tail lamp may have a protective member that protects the organic light-emitting element. The protective member may be made up of any material, so long as the material has a certain degree of high strength and is transparent; the protective member is preferably made up of polycarbonate or the like. For instance a furandicarboxylic acid derivative or an acrylonitrile derivative may be mixed with the polycarbonate.

The automobile 1500 may have a vehicle body 1503, and a window 1502 attached to the vehicle body 1503. The window may be a transparent display, unless the purpose of the window is to look ahead and behind the automobile. The transparent display may have the organic light-emitting element according to the present embodiment. In that case, constituent materials such as the electrodes of the organic light-emitting element are made up of transparent members.

The moving body having the organic light-emitting element according to the present embodiment may be for instance a vessel, an aircraft or a drone. The moving body may have a body frame and a lamp provided on the body frame. The lamp may emit light for indicating the position of the body frame. The lamp has the organic light-emitting element according to the present embodiment.

Also, the display device having the organic light-emitting element of the present embodiment can be used in a system that can be worn as a wearable device, such as smart glasses, HMDs or smart contacts. An imaging display device used in such an application example may have an imaging device capable of photoelectrically converting visible light, and a display device capable of emitting visible light.

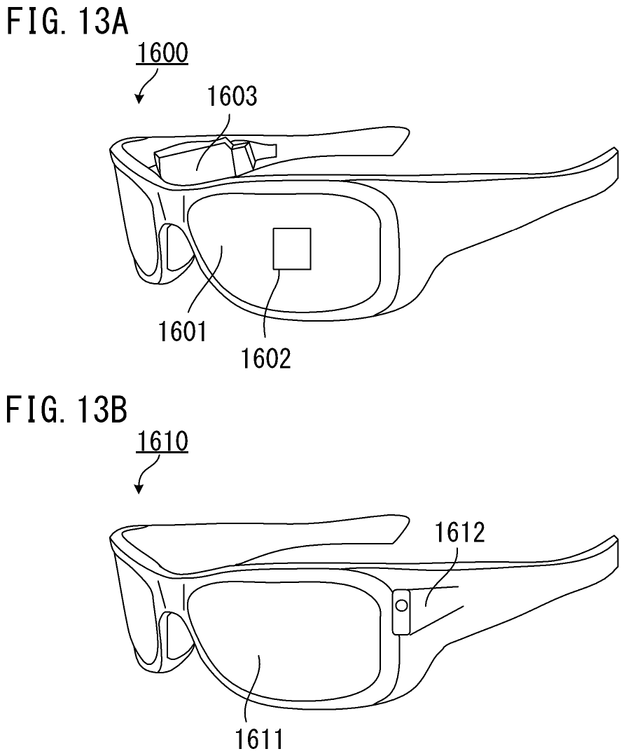

FIG. 13A illustrates spectacles 1600 (smart glasses) according to an application example of the display device having the organic light-emitting element of the present embodiment. An imaging device 1602 such as a CMOS sensor or a SPAD is provided on the front surface side of a lens 1601 of the spectacles 1600. A display device of the embodiments described above is provided on the back surface side of the lens 1601.

The spectacles 1600 further have a control device 1603. The control device 1603 functions as a power supply that supplies power to the imaging device 1602 and to the display device according to the embodiments. The control device 1603 controls the operations of the imaging device 1602 and of the display device. The lens 1601 has formed therein an optical system for condensing light onto the imaging device 1602.

FIG. 13B illustrates spectacles 1610 (smart glasses) according to another application example of the display device having the organic light-emitting element of the present embodiment. The spectacles 1610 have a control device 1612. The control device 1612 has mounted therein an imaging device corresponding to the imaging device 1602, and a display device. In a lens 1611 there is formed an optical system for projecting the light emitted by the display device in the control device 1612, such that an image is projected onto the lens 1611. The control device 1612 functions as a power supply that supplies power to the imaging device and to the display device, and controls the operations of the imaging device and of the display device. The control device may have a line-of-sight detection unit that detects the line of sight of the wearer. Infrared rays may be used herein for line-of-sight detection. An infrared light-emitting unit emits infrared light towards one eyeball of a user who is gazing at a display image. The infrared light emitted is reflected by the eyeball, and is detected by an imaging unit having a light-receiving element, whereby a captured image of the eyeball is obtained as a result. Impairment of the appearance of the image is reduced herein by having a reducing means for reducing light from the infrared light-emitting unit to the display unit, in a plan view.

The line of sight of the user with respect to the display image is detected on the basis of the captured image of the eyeball obtained through infrared light capture. Any known method can be adopted for line-of-sight detection using the captured image of the eyeball. As an example, a line-of-sight detection method can be resorted to that utilizes Purkinje images obtained through reflection of irradiation light on the cornea. More specifically, line-of-sight detection processing based on a pupillary-corneal reflection method is carried out herein. The line of sight of the user is detected by calculating a line-of-sight vector that represents the orientation (rotation angle) of the eyeball, on the basis of a Purkinje image and a pupil image included in the captured image of the eyeball, in accordance with a pupillary-corneal reflection method.

The display device having the organic light-emitting element according to the present embodiment may have an imaging device having a light-receiving element, and may control the display image of the display device on the basis of line-of-sight information about the user, from the imaging device.

Specifically, a first visual field area gazed at by the user and a second visual field area, other than the first visual field area, are determined in the display device on the basis of line-of-sight information. The first visual field area and the second visual field area may be determined by the control device of the display device; alternatively, the display device may receive visual field areas determined by an external control device. In a display area of the display device, the display resolution in the first visual field area may be controlled to be higher than the display resolution in the second visual field area. That is, the resolution in the second visual field area may set to be lower than that of the first visual field area.

The display area may have a first display area and a second display area different from the first display area, such that the display device selects the area of higher priority, from among the first display area and the second display area, on the basis of the line-of-sight information. The first display area and the second display area may be determined by the control device of the display device; alternatively, the display device may receive display areas determined by an external control device. The display device may control the resolution in a high-priority area so as to be higher than the resolution in areas other than high-priority areas. That is, the display device may lower the resolution in areas of relatively low priority.

Herein AI (Artificial Intelligence) may be used to determine the first visual field area and high-priority areas. The AI may be a model constructed to estimate, from an image of the eyeball, a line-of-sight angle, and the distance to an object lying ahead in the line of sight, using training data in the form of the image of the eyeball and the direction towards which the eyeball in the image was actually gazing at. An AI program may be provided in the display device, in the imaging device, or in an external device. In a case where an external device has the AI program, the AI program is transmitted to the display device via communication from the external device.

In a case where the display device performs display control on the basis of on visual recognition detection, the display device can be preferably used in smart glasses further having an imaging device that captures images of the exterior. The smart glasses can display captured external information in real time.

As described above, by using an apparatus including the organic light-emitting element according to the present embodiments, display with good image quality that is stable, when display is performed for a long time, can be implemented.

According to the light-emitting element of the present disclosure, multi-gradation of each pixel can be implemented without complicating the configuration of the circuits to drive the light-emitting element.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-206722, filed on Dec. 23, 2022, which is hereby incorporated by reference herein in its entirety.

What is claimed is:

1. A light-emitting element comprising:
a pixel;
an emitter disposed in the pixel; and
a light-shielding layer configured to shield light emitted by the emitter, wherein
the emitter includes a first light-emitting portion and a second light-emitting portion which emits light of an emission color of the first light-emitting portion,
the light-shielding layer includes a first opening portion where light emitted by the first light-emitting portion transmits through, and a second opening portion where light emitted by the second light-emitting portion transmits through, and
an opening area of the second opening portion is smaller than an opening area of the first opening portion.

2. The light-emitting element according to claim 1, wherein
each of the first light-emitting portion and the second light-emitting portion is constituted of an organic electroluminescence (EL) element.

3. The light-emitting element according to claim 1, wherein
the opening area of the second light-emitting portion is at least 0.3 times and not more than 0.6 times of the opening area of the first light-emitting portion.

4. The light-emitting element according to claim 1, wherein
the opening area of the second light-emitting portion is at least 0.05 times and not more than 0.3 times of the opening area of the first light-emitting portion.

5. The light-emitting element according to claim 1, wherein
a color filter is disposed on an upper part of the emitter.

6. The light-emitting element according to claim 5, wherein
the color filter is disposed so as to overlap with only one of the first opening portion and the second opening portion.

7. The light-emitting element according to claim 5, wherein
the color filter is disposed so as to overlap with both the first opening portion and the second opening portion.

8. The light-emitting element according to claim 5, wherein
the color filter is formed integrally with the light-shielding layer.

9. The light-emitting element according to claim 5, wherein
a micro-lens is disposed on an upper part of the color filter.

10. The light-emitting element according to claim 9, wherein
a first micro-lens is disposed on an upper part of the first light-emitting portion, and
a second micro-lens having a same shape as the shape of the first micro-lens is disposed on an upper part of the second light-emitting portion.

11. The light-emitting element according to claim 9, wherein
the micro-lens is disposed so as to overlap with both the first light-emitting portion and the second light-emitting portion.

12. The light-emitting element according to claim 1, wherein
in a top view of the light-emitting element, a distance between an opening center of the first opening portion and an opening center of the second opening portion is smaller than an opening size of the first opening portion.

13. The light-emitting element according to claim 1, wherein
in a top view of the light-emitting element, a distance between an opening center of the first light-emitting portion and an opening center of the second light-emitting portion is larger than an opening size of the first light-emitting portion.

14. The light-emitting element according to claim 1, wherein
the light-shielding layer is formed of a resin material or a metal material.

15. The light-emitting element according to claim 1, wherein
a pixel that emits light of a color different from the pixel includes only one opening portion where light of the light-emitting portion transmits through.

16. A display device, comprising a plurality of pixels, wherein
at least one of the plurality of pixels includes the light-emitting element according to claim 1, and a transistor connected to the light-emitting element.

17. A photoelectric conversion device comprising:
an optical unit including a plurality of lenses;
an image pickup element configured to receive light that passed the optical unit; and
a display unit configured to display an image captured by the image pickup element, wherein
the display unit includes the light-emitting element according to claim 1.

18. An electronic apparatus comprising:
a display unit including the light-emitting element according to claim 1;
a casing in which the display unit is installed; and
a communication unit which is installed in the casing and communicates with the outside.

19. An illumination device comprising:
a light source including the light-emitting element according to claim 1; and
an optical diffusion unit or an optical film where light emitted by the light source transmits through.

20. A moving body comprising:
a lighting unit including the light-emitting element according to claim 1; and
a body in which the lighting unit is installed.
